(19) United States
(12) Patent Application Publication
(10) Pub. No.: US 2009/0167953 A1
(43) Pub. Date: Jul. 2, 2009

(54) APPARATUS AND METHOD FOR CORRECTION OF SIGNAL DISTORTION

(75) Inventors: Martin Van Der Grinten, Berlin (DE); Nico Bergmann, Berlin (DE); Stefan Groessler, Berlin (DE)

Correspondence Address: SUGHRUE MION, PLLC, 2100 Pennsylvania Avenue, N.W., Washington, DC, 20037, US

(73) Assignee: BURMESTER AUDIOSYSTEME GmbH, Berlin (DE)

(21) Appl. No.: 12/344,170

(22) Filed: Dec. 24, 2008

(30) Foreign Application Priority Data
Dec. 27, 2007 (DE) 102007062752.3

(51) Int. Cl. H04N 5/00; H03M 1/00

(52) U.S. Cl. 348/607; 341/126; 348/E05.001

(57) ABSTRACT

A method is provided for correction of signal distortion, wherein the method comprises the steps of reading in a digital input signal value, determining a digital output signal value on the basis of the digital input signal value that has been read in, and outputting the digital output signal value to a signal processing path, wherein the digital output signal value is determined such that a predetermined systematic error of signal processing by the signal processing path with regard to the digital input signal value is compensated for.

The present invention relates to an apparatus and a method for correction of signal distortion, and to a method for production of an apparatus such as this.

Audio signals and video signals are nowadays generally stored in digital form. Typical storage media are, for example, CDs and DVDs, but any other desired digital data storage media are also suitable for signal storage. However, when the digital signals are reproduced, they must be converted back to analog signals. For example, the digital audio signal read from a CD is converted to an analog signal before amplification. This conversion is carried out by means of a digital/analog converter (D/A converter) which is known in the prior art. D/A converters such as these have errors, in particular linearity errors, monotonicity errors and also offset errors. In other words, if the analog signal which is output at the analog output of the D/A converter is compared with the digital input signal, then it is typically found that the analog output always has a minimum voltage, the so-called offset voltage, and the characteristic of the D/A converter from then on is non-linear and is not necessarily monotonic. As a result of this error, the signal which is output at the analog output of the D/A converter is distorted with respect to the digital input signal. Further signal distortion takes place, for example, as a result of the subsequent amplification of the analog audio signal. The output analog signal is therefore distorted in comparison to the digital signal read from the digital data storage medium. Distortion such as this may, for example, be audible in audio signals, and may thus lead to corrupted reproduction of the original sound.

With regard to the abovementioned disadvantages of the prior art, the present invention proposes a method as claimed in claim 1 and a correction apparatus as claimed in claim 13. Furthermore, the present invention proposes an apparatus for processing a digital audio signal as claimed in claim 19, and a production method for an apparatus such as this as claimed in claim 21. Further aspects, advantages and details of the present invention are specified in the dependent claims, the description and the attached drawings.

According to a first exemplary embodiment of the present invention, a method is provided for correction of signal distortion, in which a digital input signal value is read in, a digital output signal value is determined on the basis of the digital input signal value that has been read in, and the digital output signals value is output to a signal processing path. In this case, the digital output signal value is determined such that a predetermined systematic error of signal processing by the signal processing path with regard to the digital input signal value is compensated for.

The above correction method makes it possible to compensate for known systematic errors in the downstream signal processing path. In this case, the compensation is carried out in such a manner than the digital input value that is read in is replaced by a digital output value which, after passing through the downstream signal processing path and being subject to the areas which occur systematically in this case, leads to an (analog) output signal which corresponds to the digital input signal. The knowledge of the systematic error in the signal processing path is therefore used by the digital signal that is fed into the signal processing path already taking account of this error. The signal which is output from the digital processing path therefore corresponds to the original input signal.

According to a further exemplary embodiment, the predetermined systematic error is determined by means of a transfer function of the signal processing path. For example, the transfer function of the signal processing path can be measured before carrying out the correction method, for this purpose.

According to yet another exemplary embodiment, the digital output signal values are provided in the form of a look-up table. In particular, in this case, the digital input signal value may be used as an index value in the look-up table.

This allows the correction method to be carried out particularly quickly since no calculations are required. The information about the systematic errors in the signal processing path is in this case coded in its entirety in the look-up table.

According to a further exemplary embodiment, the predetermined systematic error may include at least one systematic error of conversion of a digital signal value to an analog signal. In particular, the systematic error of conversion of the digital signal value to an analog signal may comprise an offset error and/or a linearization error and/or a monotonicity error. According to one exemplary embodiment, the method also comprises the conversion of the digital output signal value to an analog signal.

As already stated initially, a digital input signal must finally be converted to an analog output signal in order, for example, to be capable of being output as a sound via a loudspeaker. Conversion from digital signals to analog signals is therefore a typical application in which systematic errors such as these may occur.

According to one development of the present invention, the predetermined systematic error may contain at least one systematic error of gain of an analog signal which is obtained from the digital output signal. In particular, in this case, the systematic error of gain of the analog signal may comprise non-linear distortion. According to one exemplary embodiment, the correction method may therefore also contain the amplification of an analog signal which is obtained from the digital output signal value.

This makes it possible to compensate not only for systematic errors in the D/A conversion of the input signal but also errors in the subsequent amplification of the analog signal. This makes it possible, for example for digital audio data, for instance music, for the sound which is finally output from a loudspeaker to be as similar as possible to the audio data read in, for example, from a CD.

According to a further exemplary embodiment of the present invention, an apparatus is provided for correction of signal distortion, which comprises means for reading in a digital input signal value and means for determining a digital output signal value on the basis of the digital input signal value that is read in. In this case, the digital output signal value is determined such that a predetermined systematic error of downstream signal processing by as signal processing path with regard to the digital input signal value in compensated for. Furthermore, the apparatus comprises means for outputting the digital output signal value to the signal processing path.

The apparatus described above can be used to compensate for known systematic errors in a signal transmission path which is connected downstream from the apparatus. In this case, the apparatus designed such that the digital input value that has been read in is replaced by a digital output value which, after passing through the downstream signal processing path and being subjected to the errors which occur systematically in this case, leads to an (analog) output signal which corresponds to the digital input signal. The apparatus therefore uses the knowledge of the systematic errors of the downstream signal processing path by shifting the digital signal that is fed into the signal processing path at this stage such that the errors which now act on the shifted signal lead to an output signal which corresponds to the original input signal.

According to one exemplary embodiment of the present invention, the apparatus is a microcontroller. However, the present invention can also be implemented by means of a microprocessor or a digital signal processor.

According to one development of the present invention, a shield is provided, which largely prevents the apparatus from being inadvertently influenced by a clock signal. For example, the shield may comprise a metal housing.

This makes it possible to effectively prevent a radio-frequency clock signal from being injected, and thus adversely affecting the operation of the correction apparatus.

According to developments of the present invention, the correction method and the associated correction apparatus can advantageously be used in particular for CD players, DVD players, preamplifiers, full amplifiers, surround processors, digital tuners, DVBT tuners, DAB tuners, SACD players and HD-DVD players. The correction method and the associated correction apparatus can likewise be used for players based on the BluRay® Standard.

According to one exemplary embodiment of the present invention, a production method for an apparatus for processing a digital audio signal comprises the provision of a predetermined test signal to a signal processing path, the determination of an output signal which is produced by the signal processing path on the basis of the test signal, the determination of a systematic error of the signal processing path on the basis of the test signal and of the output signal, the determination of an association between digital input signal values and digital output signal values, such that the determined systematic error of the signal processing path with regard to the digital input signal value is compensated for by the digital output signal value, and the provision of the determined association in the apparatus for correction of signal distortion. In particular, in this case, the systematic error can be determined by means of a transfer function of the signal processing path. According to one development, the association may be provided in the form of a look-up table.

Exemplary embodiments of the present invention will now be explained with reference to the attached drawings, in which:

FIG. 1 shows a typical systematic error, as can be compensated for by a correction method according to exemplary embodiments of the present invention.

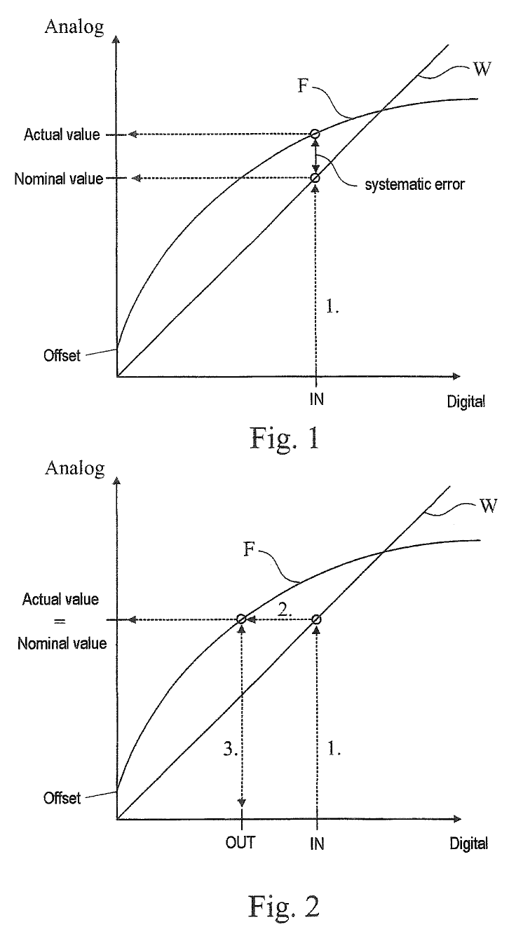

FIG. 2 shows the basic principle of a correction method according to one exemplary embodiment of the present invention.

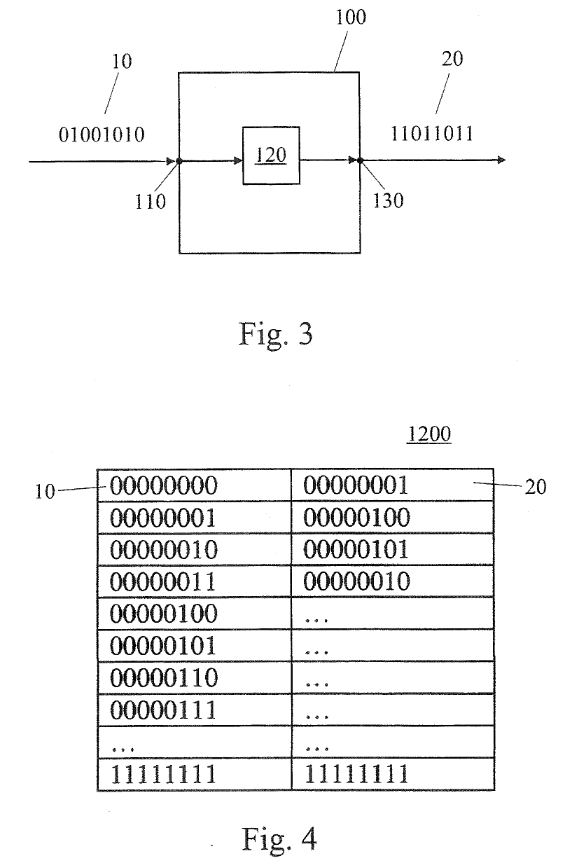

FIG. 3 shows a schematic illustration of a correction apparatus according to one exemplary embodiment of the present invention.

FIG. 4 shows an example of a look-up table, as will be used according to exemplary embodiments of the present invention.

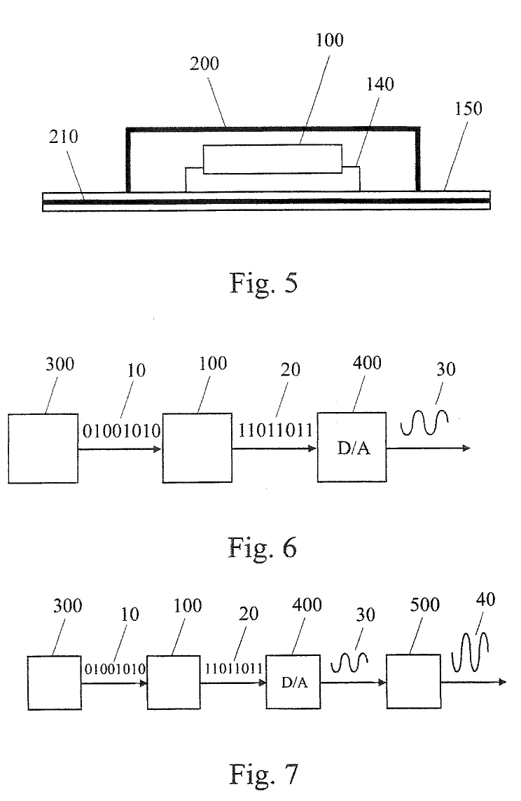

FIG. 5 shows a side section view of a correction apparatus according to one exemplary embodiment of the present invention.

FIG. 6 shows a block diagram of an apparatus according to one exemplary embodiment of the present invention.

FIG. 7 shows a block diagram of a development of the apparatus shown in FIG. 6, according to one exemplary embodiment of the present invention.

By way of example, FIG. 1 shows a systematic error as can be compensated for by a correction method according to exemplary embodiments of the present invention. In this case, the error problem will be described by way of example with reference to a D/A conversion, but in principle is also applicable to other systematic errors which occur during signal processing. In FIG. 1, the signal value IN of a digital input signal, for example of a digital audio signal read from a CD, is plotted on the abscissa. If the D/A conversion were correct, then the corresponding analog output value would have to be produced by mirroring of the digital input value IN onto the angle bisector W on the ordinate. Since D/A conversion which is as exact as possible is desirable, this output value which is reflected on the angle bisector corresponds to a nominal output value. As already described above, the actual D/A conversion is subject to errors. A D/A conversion therefore frequently has an offset error, that is to say the output signal is shifted through a specific fixed offset value. Furthermore, the D/A conversion is also frequently non-linear and not monotonic. This is illustrated in FIG. 1, by way of example, by the transfer function F. As can be seen from FIG. 1, the digital signal input value ON is mapped by the actual transfer function F of the D/A conversion onto an actual output value, which is shifted through the systematic error.

The fundamental principle of a correction method according to one exemplary embodiment of the present invention will now be explained with reference to FIG. 2. Initially, in a first step, the digital signal input value IN is in this case mirrored on the angle bisector W in order to determine an analog nominal output value. In a second step, the point on the actual transfer function F, which is subject to an error, is now determined, and likewise produces this nominal output value. This point on the actual transfer function F which is subject to an error is now projected back onto the abscissa in order to find a shifted digital output value OUT. If this shifted digital value OFF is now subjected to D/A conversion, then the D/A conversion results in an analog actual output value which corresponds to the nominal output value of the original signal input value IN. This allows the systematic errors from D/A conversion to be compensated for on the basis of the knowledge of the transfer function F by determination of a shifted digital value OUT. In particular, this makes it possible to compensate for the offset errors and/or linearization errors and/or monotonicity errors which occur during the conversion of the digital signal value to an analog signal.

The correction method described above by way of example on the basis of D/A conversion may, of course, be applied to any signal processing path whose systematic errors, that is to say discrepancies from the ideal transfer function, are known. In particular, the described method is also applicable to other, in particular more complex, transfer functions than the identity (angle bisector) described by way of example here. The described correction method can therefore be used to compensate for the predetermined systematic errors in signal processing by any desired signal processing path.

Typically, in the case of correction methods according to exemplary embodiments of the present invention, the predetermined systematic error is determined by means of a transfer function of the signal processing path. The transfer function of the signal processing path may be measured, for example, by means of a test signal for this purpose. In this case, a predetermined test signal is provided as the input signal to the signal processing path to be measured, and the output signal produced by the signal processing path on the basis of the test signal is measured. Systematic errors on the signal processing path can then be determined, for example on the basis of a transfer function, using the test signal and the output signal. The association as described above between digital input signal values and digital output signal values can then be carried out in such a way that the determined systematic error on the signal processing path with regard to the digital input signal value is compensated for by the digital output signal value. According to one embodiment of the present invention, the association between input and output values may be provided in the form of a look-up table.

FIG. 3 shows a schematic illustration of a correction apparatus 100 according to one exemplary embodiment of the present invention. In this case, the apparatus 100 for correction of signal distortion comprises means 110 for reading in a digital input signal value 10. By way of example, this digital input signal value may be a digital audio signal. Furthermore, the apparatus 100 comprises means 120 for determining a digital output signal value 20 on the basis of the digital input signal value 10 that is read in. In this case, the digital output signal value 20 is determined such that a predetermined systematic error of downstream signal processing by a signal processing path with regard to the digital input signal value 10 is compensated for. This allows such compensation to be carried out as has already been explained above with reference to FIGS. 1 and 2. Furthermore, the correction apparatus 100 comprises means 130 for outputting the digital output signal value 20 to the signal processing path. The means 120 for determining the digital output signal value are typically in the form of a microcontroller, although the means 120 for determining the digital output signal value may also be in the form of a microprocessor or a digital signal processor. In this case, according to one exemplary embodiment, a plurality of digital output signal values 20 are provided in the form of a look-up table in the means 120 for determining a digital output signal value.

This will now be explained in more detail with reference to FIG. 4. FIG. 4 shows one example of a look-up table 1200 as can be used according to exemplary embodiments of the present invention. In this case, every possible digital input signal value 10 is associated with a correspondingly shifted output signal value 20. These shifted output signal values 20 can be found by means of the method as described in FIG. 2, for example by measurement of the transfer function F of the signal processing path. According to one development of the present invention, the digital input signal value 10 is used as an index value for the look-up table 1200. This allows the shifted output signal value 20 to be associated particularly quickly and easily, since no calculations are required. The information about the systematic errors and the signal processing path is in this case clearly completely in the look-up table 1200.

FIG. 5 shows a side section view of a correction apparatus 100 according to one exemplary embodiment of the present invention. In this case, the correction apparatus 100 is in the form of a microcontroller, and is mounted on a printed circuit board 150 by means of connections 140. The correction apparatus 100 also comprises a shield 200, 210 which largely prevents the correction apparatus 100 from being inadvertently influenced. In particular, the injection of radio-frequency clock signals could disadvantageously influence the operation of the correction apparatus 100. The shield comprises a metal housing 200 which is placed on the printed circuit board and surrounds five sides of the correction apparatus. By way of example, the metal housing 200 may be composed of copper. According to one development, the printed circuit board may be a multilayer printed circuit board, in particular a 4-layer printed circuit board, with one of the plurality of layers being a metallic shielding layer 210. This also allows the correction apparatus 100 to be protected, from the printed circuit board side, against undesirable injection of interference signals, for example clock signals.

FIG. 6 shows a block diagram of an apparatus for processing a digital audio signal according to one exemplary embodiment of the present invention. The apparatus in this case comprises means 300 for providing a digital audio signal 10. An apparatus such as this could, for example, be an apparatus for reading digital audio data in a CD player, a DVD player, a surround processor, a digital tuner, a DVBT tuner, a DAB tuner, an SACD player and an HD-DVD player. The means could likewise be provided in a player according to the BluRay® Standard. The means 300 provides the digital audio signal 10 that is read out to an apparatus 100 for correction of signal distortion. Furthermore, a signal processing path 400 is connected downstream from the correction apparatus 100. In the exemplary illustrated in FIG. 6, the signal processing path 400 is a D/A converter which outputs an analog audio signal 30. The transfer function F of the D/A converter 400 is known, for example from previous measurements, and is stored in coded form in a look-up table 1200 in the correction apparatus 100. An audio input signal 10 which is provided from the reading means 300 to the correction apparatus 100 is thus converted by the correction apparatus 100 to a digital audio output signal 20. The correction apparatus 100 now passes this digital audio output signal 20 to the D/A converter 400, which converts the digital audio output signal 20 to an analog audio signal 30. Since the specific distortion of the D/A converter 400, for example offset error and/or linearization error and/or monotonicity error, have already been taken into account in the output signal 20 which is output from the correction apparatus 100, the analog audio signal 30 which is output from the D/A converter corresponds to the digital input signal 10.

FIG. 7 shows a block diagram of one development of the apparatus shown in FIG. 6, according to a further exemplary embodiment of the present invention. In this case, the fundamental design is the same, but the signal processing path comprises not only the D/A converter 400 but also an amplifier 500 which amplifies the analog audio signal 30, which is output from the D/A converter 400, and outputs the amplified audio signal 40. By way of example, the amplifier 500 may be a full amplifier, and may output the amplified audio signal 40 to a loudspeaker. According to another exemplary embodiment, the amplifier 500 may be a preamplifier, and may output the amplified audio signal 40 to an amplifier output stage. In any case, it should be noted that the amplifier 500 also typically does not operate completely linearly over the entire amplification range, thus resulting in the amplified output signal 40 being distorted with respect to the analog amplifier input signal 30. This distortion caused by the amplifier can likewise be taken into account by the correction apparatus 100, provided that it is of a systematic nature and is known in advance. In this case, the digital output signal 20 which is output from the correction apparatus 100 is shifted with respect to the digital input signal 10 such that it is not the analog signal 30 which is output from the D/A converter but only the subsequently amplified analog signal 40 which corresponds to the original value 10 that was read. This means that the correction apparatus 100 can compensate not only for the errors in D/A conversion but also for the distortion caused by amplification, in such a way that the audio signal 40 which is finally output comes as close as possible to, or is identical to, the audio signal 10 originally read in from the medium.

The exemplary embodiments of the present invention described above may advantageously be used in particular for CD players, DVD players, preamplifiers, full amplifiers, surround processors, digital tuners, DVBT tuners, DAB tuners, SACD players and HD-DVD players. The correction method and the associated correction apparatus can likewise be used for players according to the BluRay® Standard.

The present invention has been explained with reference to exemplary embodiments. These exemplary embodiments should in no way be considered as being restrictive for the present invention.

1. A method for correction of signal distortion, comprising the followings steps:
(a) reading a digital input signal value,
(b) determining a digital output signal value on the basis of the digital input signal value that has been read in, and
(c) outputting the digital output signal value to a signal processing path,
wherein, in step (b), the digital output signal value is determined such that a predetermined systematic error of signal processing by the signal processing path with regard to the digital input signal value is compensated for.

2. The method as claimed in claim 1, wherein the predetermined systematic error is determined by means of a transfer function of the signal processing path.

3. The method as claimed in claim 2, wherein the transfer function of the signal processing path is measured before carrying out slips (a) to (c).

4. The method as claimed in claim 1, wherein the digital output signal values are provided in the form of a look-up table.

5. The method as claimed in claim 4, wherein the digital input signal value is used as an index value in the look-up table.

6. The method as claimed in claim 1, wherein the predetermined systematic error includes at least one systematic error of conversion of a digital signal value to an analog signal.

7. The method as claimed in claim 6, wherein the systematic error of conversion of the digital signal value to an analog signal comprises an offset error and/or a linearization error and/or a monotonicity error.

8. The method as claimed in claim 1, furthermore comprising the following step:
(d) converting the digital output signal value to an analog signal.

9. The method as claimed in claim 1, wherein the predetermined systematic error contains at least one systematic error of gain of an analog signal which is obtained from the digital output signal.

10. The method as claimed in claim 9, wherein the systematic error of gain of the analog signal comprises non-linear distortion.

11. The method as claimed in claim 1, furthermore comprising the following step:
(e) amplifying an analog signal which is obtained from the digital output signal value.

12. The method as claimed in claim 1, wherein the digital input signal value is an audio signal.

13. An apparatus (100) for correction of signal distortion, comprising
means (110) for reading in a digital input signal value (10),
means (120) for determining a digital output signal value (20) on the basis of the digital input signal value (10) that has been read in, wherein the digital output signal value (20) is determined such that a predetermined systematic error of subsequent signal processing by a signal processing path with regard to the digital input signal value (10) is compensated for, and
means (130) for outputting the digital output signal value (20) to a signal processing path.

14. The apparatus as claimed in claim 13, wherein a plurality of digital output signal values (20) are provided, in the form of a look-up table (1200), in the means (120) for determining a digital output signal value (20).

15. The apparatus as claimed in claim 14, wherein the look-up table (1200) which is provided in the means (100) for determining a digital output signal value (20) is index on the basis of digital input signal values (10).

16. The apparatus as claimed in claim 13, wherein the apparatus is a microcontroller.

17. The apparatus as claimed in claim 13, furthermore comprising a shield (200, 210) which largely prevents the apparatus from being inadvertently influenced by a clock signal.

18. The apparatus as claimed in claim 17, wherein the shield comprises a metal housing (200).

19. Apparatus for processing a digital audio signal, comprising means (300) for providing a digital audio signal (10) to an apparatus (100) for correction of signal distortion,
an apparatus (100), which is connected to these means (300), for correction of signal distortion as claimed in claim 13,
a signal processing path (400, 500) for processing a digital output signal (20) which is output by the apparatus (100) for correction of signal distortion.

20. The apparatus as claimed in claim 19, wherein the apparatus is a CD player, a DVD player, a preamplifier, a full amplifier, a surround processor, a digital tuner, a DVBT tuner, a DAB tuner, an SACD player, or an HD-DVD player.

21. A production method for an apparatus for processing a digital audio signal as claimed in claim 19, comprising the following steps:
(a) providing a predetermined test signal to a signal processing path;
(b) determining an output signal which is produced by the signal processing path on the basis of the test signal;
(c) determining a systematic error on the signal processing path on the basis of the test signal and of the output signal;
(d) determining an association between digital input signal values and digital output signal values, such that the determined systematic error of the signal processing path with regard to the digital input signal value is compensated for by the digital output signal value, and
(e) providing the determined association in the apparatus for correction of signal distortion.

22. The method as claimed in claim 21, wherein the systematic error is determined by means of a transfer function of the signal processing path.

23. The method as claimed in claim 21, wherein the association is provided in the form of a look-up table.
